(19) United States
(12) Patent Application Publication
(10) Pub. No.: US 2018/0347915 A1
(43) Pub. Date: Dec. 6, 2018

(54) HEAT DISSIPATION APPARATUS AND ASSEMBLY METHOD FOR HEAT DISSIPATION APPARATUS

(71) Applicant: Foxconn Technology Co., Ltd., New Taipei (TW)

(72) Inventor: RUNG-AN CHEN, New Taipei (TW)

(21) Appl. No.: 15/652,353

(22) Filed: Jul. 18, 2017

(30) Foreign Application Priority Data
May 31, 2017 (TW) 106117912

(51) Int. Cl. F28F 9/00

(52) U.S. Cl. CPC F28F 9/002; H05K 7/20154

(57) ABSTRACT

A small-scale but high-efficiency heat dissipation apparatus includes a frame, a blade set, and a radiator. The frame includes a base defining an accommodating space and an upper lid being configured for covering the accommodating space. The blade set and the radiator are mounted in the accommodating space, and the upper lid includes a plurality of internally threaded holes protruding away from the upper lid, and the internally threaded holes are configured to enable fixing to a heat-producing element.

### FIELD

The subject matter herein generally relates to a heat management and dissipation apparatus and an assembly method for a heat dissipation apparatus with a heat generating member.

### BACKGROUND

Heat is produced by electronic components such as integrated circuit chips during their normal operations. If the heat is not removed, these electronic components may overheat. Therefore, heat dissipation apparatuses are often used to cool these electronic components.

However, limited by the small space available for the heat dissipation apparatus, the fins received in the accommodating space must be relatively small and the heat dissipation efficiency of the heat dissipation apparatus is accordingly reduced.

Therefore, it is desirable to provide a heat dissipation apparatus which can overcome the above-mentioned disadvantages.

### BRIEF DESCRIPTION OF THE DRAWINGS

Implementations of the present technology will now be described, by way of example only, with reference to the attached figures.

FIG. 1 is an isometric view of a heat dissipation apparatus in accordance with one exemplary embodiment.

FIG. 2 is another isometric view of a heat dissipation apparatus in accordance with one exemplary embodiment.

FIG. 3 is an exploded isometric view of the heat dissipation apparatus of FIG. 1.

FIG. 4 is a cross-sectional view taken along line II-II of FIG. 1.

FIG. 5 is an isometric view of a heat dissipation apparatus being used for dissipating heat in accordance with one exemplary embodiment.

FIG. 6 is an exploded isometric view of the apparatus of FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better. The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

Several definitions that apply throughout this disclosure will now be presented.

The term “substantially” is defined to be essentially conforming to the particular dimension, shape, or other feature that the term modifies, such that the component need not be exact.

For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like. The references “a plurality of” and “a number of” mean “at least two.”

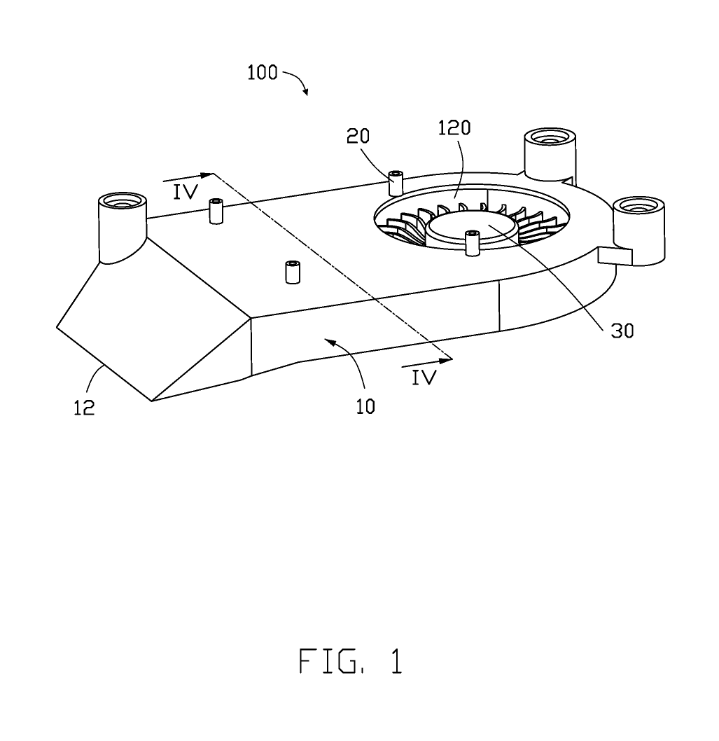

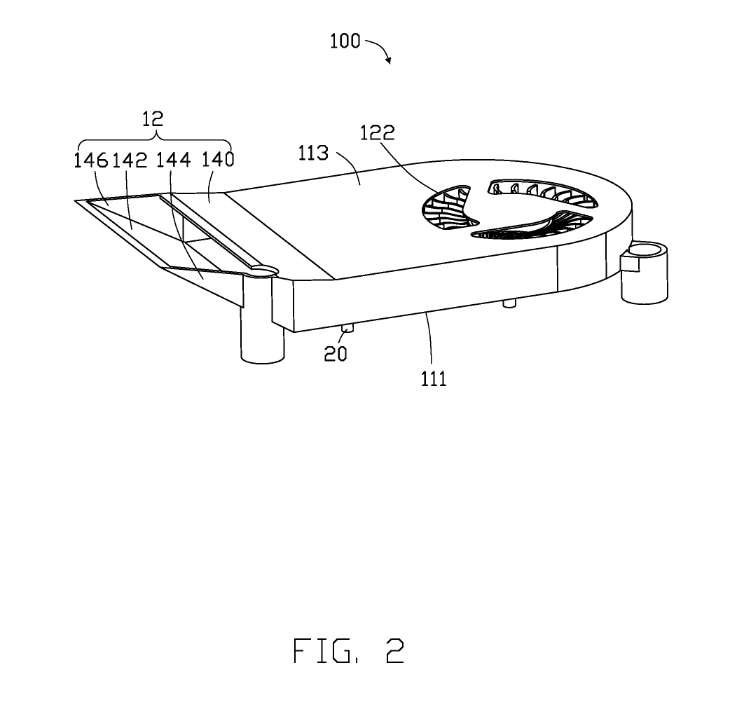

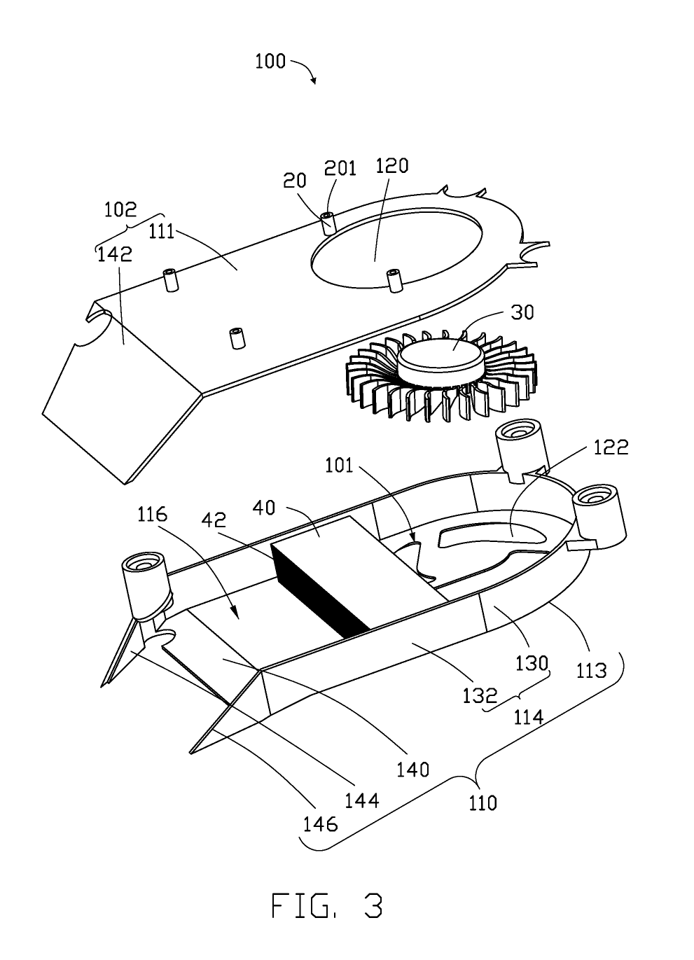

FIGS. 1-3 illustrate a heat dissipation apparatus 100 according to one embodiment. The heat dissipation apparatus 100 includes a frame 10, a blade set 30, and a radiator 40.

The frame 10 includes a base 110 and an upper lid 112. The base 110 includes a lower plate 113, a side wall 114 perpendicularly connected to the lower plate 113, a first side plate 140 connected at one end of the lower plate 113, and a first baffle 144 and a second baffle 146 opposite to the first baffle 144. The lower plate 113 defines a first air inlet 122. The first plate 140 slopes downwards.

The side wall 114 includes a curved wall 130 and two flat plates 132 connecting with the curved wall 130, and the two flat plates 132 are parallel and opposite to each other. The first baffle 144 and the second baffle 146 are substantially triangular. The first baffle 144 and the second baffle 146 are each connected with a flat plate 132. The two flat plates 132 together define an airflow channel therebetween. The lower plate 113 and the side wall 114 together form an accommodating space 101.

The frame 10 defines an air outlet 12 and an opening of the air outlet 12 is downwardly. The air outlet 12 is formed by the first side plate 140, the second side plate 142, the first baffle 144, and the second side baffle 146. Heat generated by a heat generating member is dissipated via the airflow channel 116 and the air outlet 12.

The upper lid 110 is fixed with an upper edge of the side wall 114 of the base 110 by welding or by adhesive, and the accommodating space 101 is covered by the upper lid 110.

The upper lid 110 includes an upper plate 111 and a second side plate 142 connected at one end of the upper plate 111. The upper plate 111 is parallel with the lower plate 113, and the second side plate 142 bends toward the first side plate140. The upper plate 111 defines a second air inlet 120 and the second air inlet 120 is aligned with the first air inlet 122.

Internally threaded holes 20 are formed on the upper plate 111 and integrally formed with the upper plate 111. The internally threaded holes 20 protrude away from the upper plate 111. An extending direction of the internally threaded holes 20 is away from the air outlet 12. Each internally threaded hole 20 defines an insert hole 201. The internally threaded holes 20 are configured to enable fixing thereon of a heat generating member 50.

The blade set 30 is mounted in the accommodating space 101 adjacent to the first air inlet 122 and the second air inlet 120. In the embodiment, the blade set 30 is a centrifugal blower and can rotate along a central shaft (motor not shown).

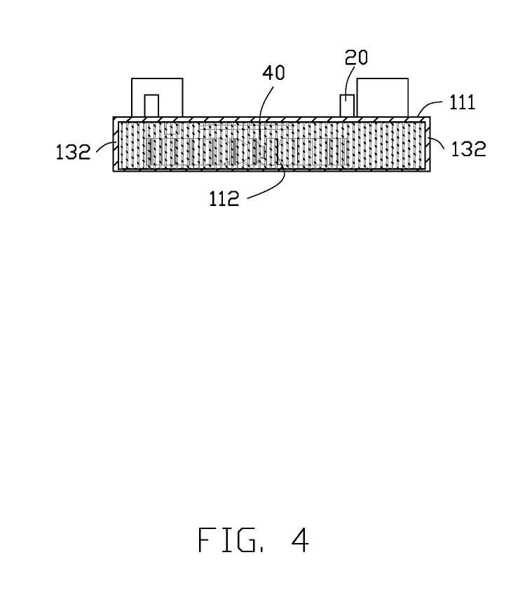

The radiator 40 is mounted in the airflow channel 116 and between the air outlet 12 and the blade set 30. The radiator 40 includes a plurality of heat dissipation fins 42 spaced apart from each other, and a material of the heat dissipation fins 42 is copper alloy. In this exemplary embodiment, the radiator 40 is fixed with the lower plate 113 by welding, thus there is no need for a plurality of screw holes to lock the radiator 40 on the lower plate 113. In this way, a length of the radiator is kept consistent with a width of the airflow channel 116, as shown in FIG. 4, and noise produced by the rotation of the blade set 30 is also reduced.

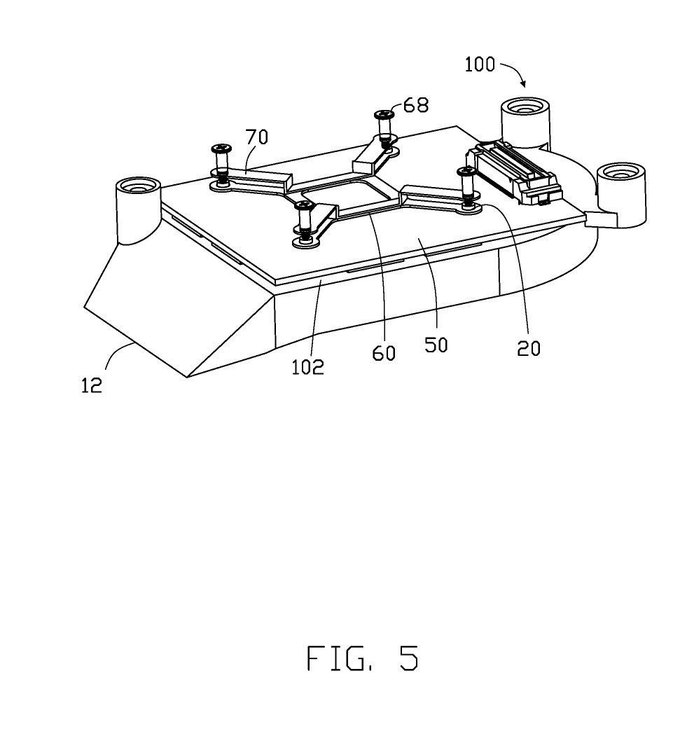

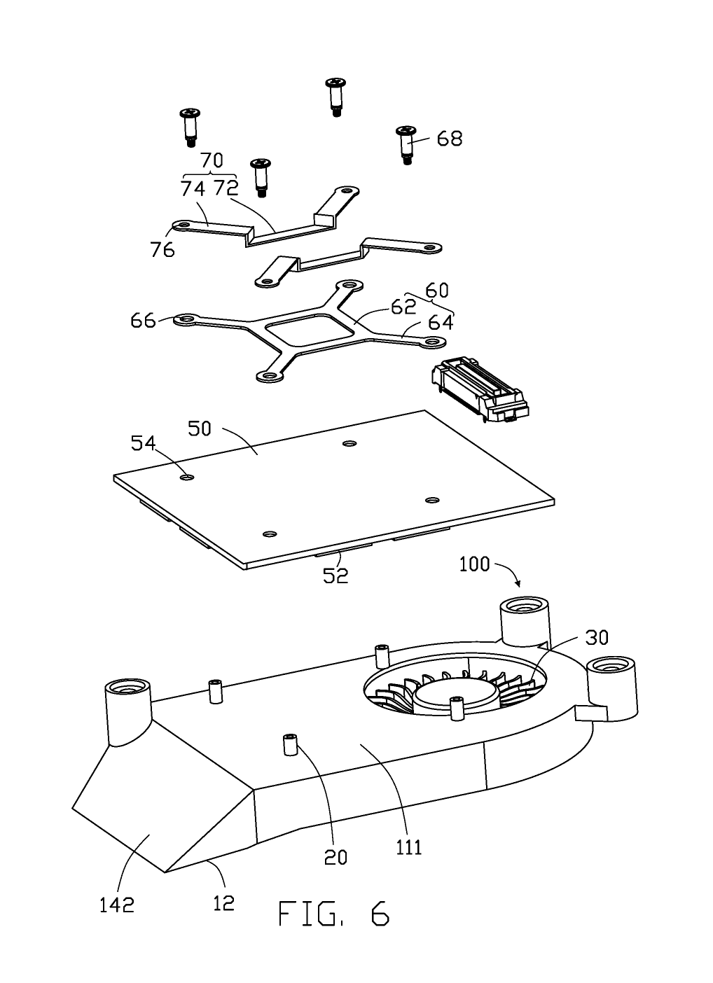

The disclosure also provides an assembly method of the heat dissipation apparatus 100 with a heat generating member(shown in FIG. 5 and FIG. 6). The assembly method is provided by way of example as there are a variety of ways to carry out the assembly method. The assembly method can begin at block 301.

At block 301, a plurality of screws 68 and a heat generating member 50 are provided. In this embodiment, the heat generating member 50 is a motherboard and a plurality of electrical elements 52 are mounted on the motherboard.

At block 302, a plurality of positioning holes 54 are formed on the heat generating member 50, and the positioning holes 54 correspond to the internally threaded holes 20.

At block 303, the heat generating member 50 is disposed on the heat dissipation apparatus 100, the surface with the electrical elements 52 being toward the upper plate 111. The positioning holes 54 pass through the internally threaded holes 20, and the screws 68 are inserted in the insert hole 201 of the internally threaded holes 20, and the heat generating member 50 is fixed on the heat dissipation apparatus 100 using the screws 68.

In a preferred embodiment, before fixing the heat generating member 50 on the heat dissipation apparatus 100, there is a step of providing a fixing board 60 and two supporting arms 70. The fixing board 60 and the supporting arms 70 are together used to firmly fix the heat generating member 50 on the heat dissipation apparatus 100.

The fixing board 60 is substantially X-shaped, and includes a base portion 62 and four fixing arms 64. The base portion 62 is substantially square, and the fixing arms 64 extend away from the base portion 62 from the corners of the base portion 62. Each end of the fixing arm 64 comprises a first mounting hole 66, and the fixing board 60 is disposed on the heat generating member 50, and each mounting hole 54 passes through one internally threaded hole 20.

Each supporting arm 70 includes a fitting portion 72 and two bendable portions 74 connected at opposite ends of the fitting portion 72. The bendable portion 74 is substantially L-shaped. Each end of the bendable portion 74 includes a second mounting hole 76. The fitting portion 72 is disposed on the base portion 62, and the bendable portion 74 is located parallel to and spaced away from the fixing arm 64, and the first mounting hole 66 corresponds to the second mounting hole 76.

Then, the screws 68 are applied over the second mounting hole 76, the first mounting hole 66, the positioning hole 54, and the insert hole 201 and screwed together with the internally threaded holes 20.

When the heat dissipation apparatus 100 is in use, heat generated by the heat generating member 50 is transferred to the radiator 40 directly. The first inlet 120 and the second inlet 122 suck in cooling air from outside, and the blade set 30 is configured to rotate to push the cooling air to the radiator 40 and out via the air outlet 12, and then the heat from the radiator 40 is taken away.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A heat dissipation apparatus comprising:
a frame comprising a base defining an accommodating space and an upper lid being configured for covering the accommodating space;
a blade set, and a radiator being mounted in the accommodating space, wherein the upper lid comprising a plurality of internally threaded holes protruding away from the upper lid, and the internally threaded holes are configured to enable fixing thereon of a heat generating member.

2. The heat dissipation apparatus of claim 1, wherein the base comprises a lower plate and a side wall perpendicularly connected to the lower plate, the lower plate comprising a first air inlet; the upper lid comprises a second air inlet align with the first air inlet, and the blade set is disposed in the accommodating space and toward the first air inlet and second air inlet.

3. The heat dissipation apparatus of claim 2, wherein the side wall comprises a curved wall and two flat plates connecting with the curved wall; and the frame comprises an air outlet opposite to the curved wall, and the radiator is arranged between the blade set and the air outlet.

4. The heat dissipation apparatus of claim 3, wherein the base further comprises a first side plate connected at one end of the lower plate, a first baffle connected with one flat plate and a second baffle connected with the other flat plate, and the first baffle is opposite to the second baffle, the first baffle and the second baffle are substantially triangular.

5. The heat dissipation apparatus of claim 4, wherein the upper lid is fixed to the base by welding or by adhesive.

6. The heat dissipation apparatus of claim 4, wherein an opening of the air outlet is downwardly.

7. The heat dissipation apparatus of claim 5, wherein the upper lid comprises an upper plate and a first side plate connected at one end of the upper plate, the upper plate is parallel with the lower plate, and the first side plate is angled toward the base; and the first side plate, the second side plate and the two baffles together form the air outlet.

8. The heat dissipation apparatus of claim 1, wherein the radiator comprises a plurality of heat dissipation fins space apart each other.

9. The heat dissipation apparatus of claim 8, wherein the material comprising the heat dissipation fins is copper alloy.

10. The heat dissipation apparatus of claim 1, wherein the upper lid and the internally threaded holes are integrally formed.

11. The heat dissipation apparatus of claim 7, wherein the two flat plates defines an airflow channel therebetween, and the radiator is mounted in the airflow channel, and a length of the radiator is equal to a distance between of the two flat plates.

12. The heat dissipation apparatus of claim 1, wherein each internally threaded holes defines an insert hole to receive a screw.

13. An assembly method for a heat dissipation apparatus with a heat generating member comprising:
providing a heat dissipation apparatus, the heat dissipation apparatus comprising a frame, a blade set and a radiator; the frame comprising a base defining an accommodating space and an upper lid being configured for covering the accommodating space; the blade set and the radiator being arranged on the accommodating space, wherein the upper lid comprising a plurality of internally threaded holes protruding away from the upper lid, and the internally threaded holes are configured to fix a heat generating member thereon;
providing a plurality of screws and a heat generating member;
forming a plurality of positioning holes on the heat generating member, and the positioning holes are corresponding to the internally threaded holes;
letting the positioning holes passing through the internally threaded holes, and letting the screws insert in the internally threaded holes, and using the screw to fixed the heat generating member on the heat dissipation apparatus.

14. The assembly method of claim 13, wherein the heat generating member is motherboard.

15. The assembly method of claim 13, wherein the method further comprises providing a fixing board, and the fixing board is substantially X-shaped, and comprising a base portion and four fixing arms, the base portion is substantially square shaped, and the fixing arms are extended from the corners of the base portion, each end of the fixing arm comprises a first mounting hole, and the fixing board is arranged on the heat generating member, and the mounting hole passes through the stud bolt.

16. The assembly method of claim 13, wherein the method further comprises providing two supporting arms, each supporting arm comprises a fitting portion and two bendable portions connected at opposite ends of the fitting portion, and the bendable portion is substantially L-shaped, each end of the bendable portion comprises a second mounting hole, and the fitting portion is disposed on the base portion, and the bendable portion is located parallel to and spaced away from the fixing arm, and the first mounting hole is corresponded to the second mounting hole.

17. A heat dissipation apparatus comprising:
a frame comprising a base defining an accommodating space and an upper lid, the upper lid being fixed with the base by welding method and configured for covering the accommodating space;
a blade set, and a radiator being mounted in the accommodating space, wherein the upper lid comprising a plurality of internally threaded holes protruding away from the upper lid, and the internally threaded holes are configured to fix a heat generating member thereon.
